(19) United States
(12) Patent Application Publication
(10) Pub. No.: US 2026/0219325 A1
(43) Pub. Date: Jul. 30, 2026

(54) IMPEDANCE MEASUREMENT DEVICE FOR A MULTI-CHANNEL BATTERY

(71) Applicant: MONA INC., Gunsan-si (KR)

(72) Inventor: Jae Han JUNG, Seoul (KR)

(73) Assignee: MONA INC., Gunsan-si (KR)

(21) Appl. No.: 19/434,001

(22) Filed: Dec. 29, 2025

(30) Foreign Application Priority Data
Jan. 24, 2025 (KR) 10-2025-0011020

(51) Int. Cl. G01R 31/367; G01R 31/389; G01R 31/396

(52) U.S. Cl. CPC G01R 31/367; G01R 31/389; G01R 31/396

(57) ABSTRACT

One embodiment of the present invention discloses an impedance measurement device for a multi-channel battery that measures impedance in order to determine whether a battery is defective in a multi-channel battery system, wherein the impedance measurement device for a multi-channel battery includes an impedance measurement unit configured to measure impedance of a multi-channel battery including a plurality of batteries, and a sine wave application unit configured to process a sine wave and apply a sine wave to each of the batteries in order to reduce noise between the batteries.

### CROSS-REFERENCE TO RELATED APPLICATIONS

This application is based on and claims priority under 35 U.S.C. §119 to Korean Patent Application No. 10-2025-0011020 filed on January 24, 2025, in the Korean Intellectual Property Office, the disclosure of which is incorporated by reference herein in its entirety.

### BACKGROUND

The present disclosure relates to an impedance measurement device for a multi-channel battery, and more particularly, to an impedance measurement device for a multi-channel battery that measures impedance in order to determine whether a battery is defective in a multi-channel battery system.

In general, a multi-channel battery system is a system that simultaneously manages and measures a plurality of battery cells or modules, and is capable of independently measuring voltage, current, temperature, impedance, and the like for each battery, thereby monitoring a state of the battery.

Impedance measurement is one of important methods for evaluating a state of a battery. Since impedance of a battery reflects internal resistance of the battery, a state of an electrolyte, a state of an electrode, and the like, accurately measuring the impedance makes it possible to detect performance degradation or a defect of the battery at an early stage.

Impedance measurement is mainly calculated by applying an alternating current (AC) voltage to a battery and measuring a corresponding current response. Impedance is defined as a ratio of voltage to current, and electrical characteristics of the battery can generally be identified through a frequency response. In particular, electrochemical impedance spectroscopy (EIS) is widely used.

However, in a multi-channel battery system, since a plurality of battery cells are measured simultaneously, noise may occur between battery channels. Such noise affects impedance measurement and may interfere with accurate measurement.

In a multi-channel battery system, since multiple battery channels operate simultaneously, cross-interference or common-mode noise generated in each battery channel may affect measurement results. This is an important issue particularly in impedance measurement requiring high accuracy. A signal including noise reduces reliability of measurement and may cause difficulty in accurately evaluating a battery state.

### Prior art references

### Patent document

Korean Patent No. 10-2424916 (July 22, 2022)(BATTERY DIAGNOSIS METHOD AND APPARATUS)

### SUMMARY

Accordingly, an object of one embodiment of the present invention is to provide an impedance measurement device for a multi-channel battery that applies a sine wave to a multi-channel battery in a multi-channel battery system and measures impedance of the multi-channel battery in order to determine whether the battery is defective.

In order to achieve the above-described object of one embodiment of the present invention, an impedance measurement device for a multi-channel battery according to one embodiment includes an impedance measurement unit configured to measure impedance of a multi-channel battery including a plurality of batteries, and a sine wave application unit configured to process a sine wave and apply a sine wave to each of the batteries in order to reduce noise between the batteries.

In one embodiment of the present invention, the sine wave application unit may include a time-delay application unit configured to apply the sine wave to each of the batteries such that the sine waves applied to the respective batteries have a time delay.

In one embodiment of the present invention, the sine wave application unit may include a frequency-difference application unit configured to apply the sine wave to each of the batteries such that the sine waves applied to the respective batteries have a frequency difference.

In one embodiment of the present invention, the sine wave application unit may include a filter unit configured to remove noise of the sine waves applied to the respective batteries.

In order to achieve the above-described object of one embodiment of the present invention, an impedance measurement device for a multi-channel battery according to another embodiment includes an impedance measurement unit configured to measure impedance of a multi-channel battery including a plurality of batteries; a sine wave application unit configured to process a sine wave and apply a sine wave to each of the batteries in order to reduce noise between the batteries; and a control unit including an artificial intelligence model that receives multi-channel battery state information including voltage, current, temperature, and SOC, and noise state information including a frequency interference pattern and external interference signal data, outputs an optimal sine wave applied to the multi-channel battery and a noise-removed impedance spectrum, and controls the sine wave application unit based on impedance measured by the impedance measurement unit.

According to one embodiment of the present invention, by minimizing noise that may occur when simultaneously measuring a plurality of battery cells or modules in a multi-channel battery system, impedance of a battery can be accurately measured, and through this, a state of the battery can be checked to determine whether the battery is defective.

### BRIEF DESCRIPTION OF THE DRAWINGS

FIG. 1 is a block diagram for describing an impedance measurement device for a multi-channel battery according to one embodiment of the present invention.

FIG. 2 is a block diagram for describing a sine wave application unit illustrated in FIG. 1.

FIG. 3 is a graph illustrating examples of sine waves output from the sine wave application unit illustrated in FIG. 2.

FIG. 4 is a block diagram for describing an artificial intelligence model illustrated in FIG. 1.

FIG. 5 is a block diagram for describing an impedance measurement device for a multi-channel battery according to another embodiment of the present invention.

FIG. 6 is a graph illustrating an example of sine waves output from the sine wave application unit illustrated in FIG. 5.

FIG. 7 is a graph illustrating another example of sine waves output from the sine wave application unit illustrated in FIG. 5.

FIG. 8 is a block diagram for describing an impedance measurement device for a multi-channel battery according to still another embodiment of the present invention.

### DETAILED DESCRIPTION

Hereinafter, one embodiment of the present invention will be described in more detail with reference to the accompanying drawings. One embodiment of the present invention may be subject to various modifications and may have various forms, and thus specific embodiments are illustrated in the drawings and described in detail in the specification. However, this is not intended to limit one embodiment of the present invention to specific disclosed forms, and it should be understood to include all modifications, equivalents, and substitutes included within the spirit and technical scope of one embodiment of the present invention.

In describing each drawing, similar reference numerals are used for similar components. In the accompanying drawings, dimensions of structures are illustrated to be enlarged relative to actual dimensions in order to clarify one embodiment of the present invention.

Terms such as first and second may be used to describe various components, but such components should not be limited by such terms. Such terms are used only for the purpose of distinguishing one component from another component. For example, without departing from the scope of one embodiment of the present invention, a first component may be referred to as a second component, and similarly, a second component may be referred to as a first component. A singular expression includes a plural expression unless the context clearly indicates otherwise.

In this application, terms such as “include” or “have” are intended to specify the presence of features, numbers, steps, operations, components, parts, or combinations thereof described in the specification, and are not intended to preclude the presence or addition of one or more other features, numbers, steps, operations, components, parts, or combinations thereof.

In addition, unless otherwise defined, all terms used herein, including technical or scientific terms, have the same meanings as those generally understood by a person having ordinary skill in the art to which one embodiment of the present invention belongs. Terms defined in commonly used dictionaries are to be interpreted as having meanings consistent with their meanings in the context of the relevant art, and are not to be interpreted in an idealized or overly formal sense unless explicitly defined in this application.

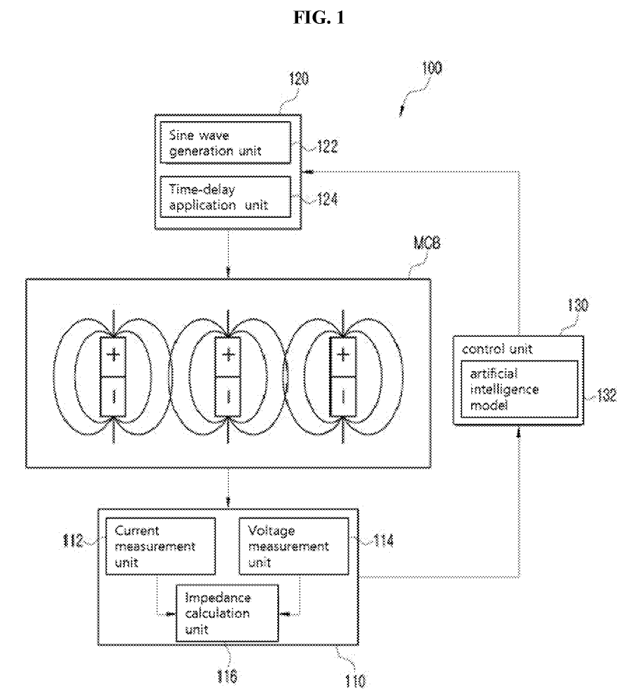

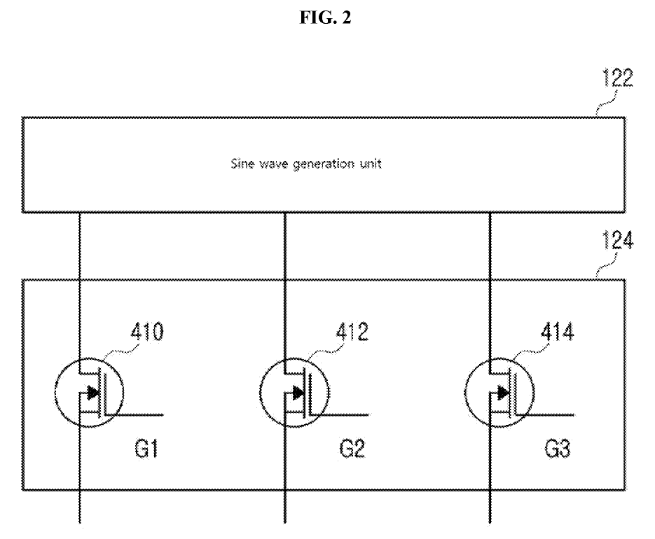

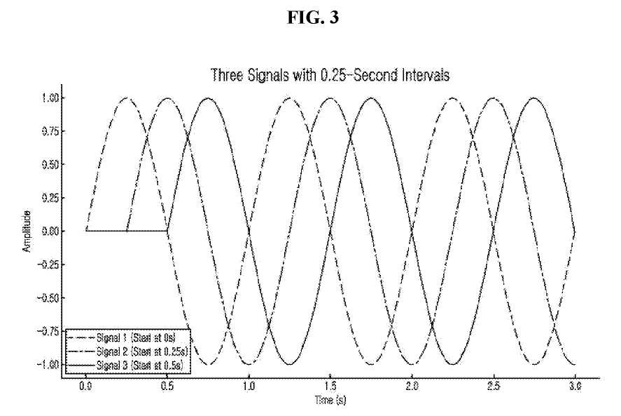

FIG. 1 is a block diagram for describing an impedance measurement device for a multi-channel battery according to one embodiment of the present invention. FIG. 2 is a block diagram for describing a sine wave application unit illustrated in FIG. 1. FIG. 3 is a graph illustrating examples of sine waves output from the sine wave application unit illustrated in FIG. 2.

Referring to FIGS. 1, 2, and 3, an impedance measurement device 100 for a multi-channel battery according to one embodiment of the present invention includes an impedance measurement unit 110, a sine wave application unit 120, and a control unit 130, and measures impedance of a multi-channel battery including a plurality of batteries.

The impedance measurement unit 110 includes a current measurement unit 112, a voltage measurement unit 114, and an impedance calculation unit 116, and measures impedance of a multi-channel battery MCB.

Specifically, the current measurement unit 112 measures a current value of the multi-channel battery MCB when a sine wave signal is applied. The current measurement unit 112 may be implemented in a configuration that directly measures current. However, in one embodiment of the present invention, the current measurement unit 112 calculates a current value by using a resistance unit having a known resistance value in order to simplify a circuit structure for current measurement. For example, the current measurement unit 112 may change a magnitude of a current signal by changing a resistance magnitude by connecting a plurality of resistors in parallel.

The voltage measurement unit 114 measures a voltage value of the multi-channel battery MCB in response to application of the sine wave signal. The voltage measurement unit 114 may be connected in series with the multi-channel battery MCB to measure a voltage of the multi-channel battery MCB.

A current value measured by the current measurement unit 112 and a voltage value measured by the voltage measurement unit 114 may be values of alternating current components from which direct current components have been removed. In order to obtain values of the alternating current components from which the direct current components have been removed, the current measurement unit 112 and the voltage measurement unit 114 may further include a configuration for removing direct current components. In addition, various conventional methods for identifying alternating current components by removing direct current components from voltage values and current values may be applied to one embodiment of the present invention.

The impedance calculation unit 116 calculates impedance of the multi-channel battery MCB based on a current value identified by the current measurement unit 112 and a voltage value identified by the voltage measurement unit 114. The impedance calculation unit 116 may identify impedance by applying a Hamming window algorithm, a discrete Fourier transform DFT Discrete Fourier Transform, and the like to a finite number of current values and voltage values identified at predetermined intervals, and by using a Nyquist plot and the like. Since a method itself for calculating impedance using a finite number of current values and voltage values that change over time is already widely known, a detailed description thereof will be omitted.

The impedance calculation unit 116 may calculate impedance of the multi-channel battery MCB with respect to sine wave signals of various frequencies. For example, the impedance calculation unit 116 may calculate a first impedance when a sine wave signal of a first frequency is applied, and calculate a second impedance when a sine wave signal of a second frequency is applied. An interval between the first frequency and the second frequency may be a logarithmic interval.

The sine wave application unit 120 includes a sine wave generation unit 122 and a time-delay application unit 124, and applies sine waves having a time delay to a multi-channel battery MCB including a plurality of batteries.

Specifically, the sine wave generation unit 122 generates sine wave signals within a predetermined frequency range. For example, the sine wave generation unit 122 may generate a plurality of sine wave signals having different frequencies within various frequency ranges from 0.1 Hz to 5 kHz. A frequency range in which the sine wave signals are generated may be variously modified depending on an embodiment. A magnitude of the sine wave signals may vary depending on an embodiment, such as several millivolts to several tens of volts.

The time-delay application unit 124 includes a plurality of switching elements, and applies sine waves to each of the batteries such that the sine waves applied to the respective batteries have a time delay. In one embodiment of the present invention, the switching elements may be implemented as MOSFETs.

That is, a first MOSFET has a drain electrode connected to the sine wave generation unit 122 and a source connected to a battery, and is turned on by receiving a first gate signal G1 through a gate, thereby applying a sine wave output from the sine wave generation unit 122 to the battery.

A second MOSFET has a drain electrode connected to the sine wave generation unit 122 and a source connected to a battery, and is turned on by receiving a second gate signal G2 at a time different from the first gate signal G1 through a gate, thereby applying a sine wave output from the sine wave generation unit 122 to the battery.

A third MOSFET has a drain electrode connected to the sine wave generation unit 122 and a source connected to a battery, and is turned on by receiving a third gate signal G3 at a time different from the second gate signal G2 through a gate, thereby applying a sine wave output from the sine wave generation unit 122 to the battery.

The sine wave application unit 120 temporally delays application timings at which an alternating current voltage is applied to each battery channel, such that measurement is performed sequentially rather than simultaneously among multiple battery channels. Through this, cross-interference between battery channels is minimized, and signals of each battery channel can be measured independently. This method prevents noise generated in different battery channels from overlapping, thereby enabling accurate impedance measurement.

Referring to FIG. 1 again, the control unit 130 includes an artificial intelligence model 132, and controls the sine wave application unit 120 based on impedance measured by the impedance measurement unit 110 so as to process and apply a sine wave in order to reduce noise between batteries.

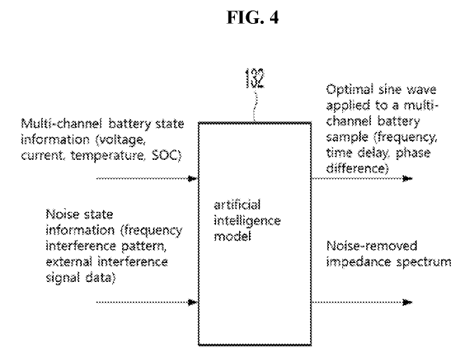

FIG. 4 is a block diagram for describing an artificial intelligence model illustrated in FIG. 1.

Referring to FIG. 4, multi-channel battery state information and noise state information are input as input values of the artificial intelligence model 132, and an optimal sine wave applied to the multi-channel battery and a noise-removed impedance spectrum are output as output values of the artificial intelligence model 132.

The multi-channel battery state information includes voltage, current, temperature, and SOC State of Charge. Here, the voltage is a voltage value measured in real time at each battery channel and is an important indicator representing a power state and a state change of the battery. The current is a current value representing a battery flow during a charging or discharging process and plays an important role in evaluating battery performance and efficiency. The temperature has an important effect on safety and efficiency of the battery, because an excessively high temperature may shorten a lifespan of the battery or cause a risk. The SOC represents a charge state of the battery and is useful for identifying charging and discharging states by expressing a current charge state as a percentage relative to a battery capacity.

The noise state information includes a frequency interference pattern and external interference signal data. Here, the frequency interference pattern is data representing distorted amplitudes and phase differences due to electromagnetic interference EMI or frequency collisions generated from a battery or other electronic devices, and is a factor that may reduce reliability of a system. The external interference signal data includes interference information generated due to electromagnetic wave interference or other abnormal signal characteristics, which may negatively affect performance of a battery or an electronic device.

The optimal sine wave is a sine wave to be applied to the multi-channel battery MCB and is a sine wave having different time delays in order to prevent signal interference between battery channels. In this embodiment, the time delay may be set to several μs to several ms.

The noise-removed impedance spectrum includes a process of analyzing impedance characteristics of a battery system through unsupervised learning and removing unnecessary noise by comparing actual full-spectrum data with measured frequency data. A difference between noise and an actual signal is analyzed, and values exhibiting a large difference are regarded as noise and removed.

In the noise-removed impedance spectrum, impedance is represented in a complex number form, that is, as a real impedance value Zreal and an imaginary impedance value Zimag. The real impedance value is a real impedance value after noise removal and represents an actual resistance component with respect to current flow of the battery system. The imaginary impedance value is an imaginary impedance value after noise removal and represents a phase change of current or an inductance component in the battery system. The real and imaginary components of impedance may vary depending on frequency. In the noise-removed impedance spectrum, the real and imaginary impedance values provide important information for accurate electrical characteristic analysis. That is, after noise removal, the real impedance value more accurately reflects an actual resistance, and the imaginary impedance value more accurately reflects a reactive characteristic of a circuit. Accurately measuring and analyzing these values in the noise-removed impedance spectrum enables accurate understanding and interpretation of electrical characteristics.

The artificial intelligence model 132 may be implemented as a convolutional neural network CNN that automatically extracts major features by receiving a two-dimensional spectrum image of a frequency signal as input and analyzes a noise pattern, a long short-term memory LSTM that analyzes temporal continuous data including voltage and current to identify correlations, and an attention mechanism that assigns weights to important noise patterns to maximize a noise removal effect.

In a case where the artificial intelligence model 132 is implemented as a CNN, a two-dimensional spectrum image of a frequency signal is input to the CNN to extract major features, and an optimal alternating current voltage and a noise-removed impedance spectrum corresponding to battery state information and noise information are output. A core of the CNN is a structure in which frequency patterns and noise characteristics are automatically learned through convolutional layers, data are compressed through pooling layers, and an optimal solution is derived in fully connected layers. In this manner, the model learns complex nonlinear relationships and plays an important role in a battery system.

In a case where the artificial intelligence model 132 is implemented as an LSTM, battery state information including voltage, current, temperature, and SOC and noise information including a frequency interference pattern and an external interference signal are treated as temporal continuous data and input to an LSTM model to analyze battery state changes and noise patterns over time and identify correlations therebetween.

In a case where the artificial intelligence model 132 is implemented as an attention mechanism, the model operates by assigning weights to important portions among input data to emphasize major patterns and suppress unnecessary information. In this model, important portions of battery state information and noise information are respectively emphasized, and in particular, high weights are assigned to noise patterns to maximize a noise removal effect. Through this, performance for accurately predicting an optimal alternating current voltage and outputting a noise-removed impedance spectrum can be improved.

Data input to the artificial intelligence model 132 may undergo a normalization process of scaling voltage data and current data to a range of 0 to 1, and a frequency filtering process of removing low-frequency noise of 10 Hz or less.

In one example, training data for the artificial intelligence model 132 may be self-generated experimental data experimentally generated to monitor or analyze a battery state, that is, a multi-channel battery state. In another example, training data for the artificial intelligence model 132 may be external electromagnetic interference and frequency distortion simulation data generated by simulating values measured in a system when electromagnetic interference or frequency distortion occurs.

The training data for the artificial intelligence model 132 may be composed of normal data noise-free impedance and noise-included data external interference and frequency collisions.

The normal data described above are data obtained from normal operation of a battery or a system and include impedance values collected in a state without external interference or noise. The normal data described above well represent normal electrical characteristics of the battery and provide values within a normal range expected in impedance analysis.

The noise-included data described above refer to data in which noise is included in impedance values due to external factors such as electromagnetic interference EMI and frequency collisions. The noise-included data described above reflect abnormal phenomena that may occur in an actual environment, and the artificial intelligence model 132 may be used to remove or analyze such noise to predict and solve problems that may occur in actual situations. Since external interference or frequency distortion affects impedance of a battery and makes accurate state analysis difficult, the artificial intelligence model 132 may learn an ability to process and filter noise through the noise-included data described above.

In one embodiment of the present invention, the artificial intelligence model 132 may be trained using an unsupervised learning technique that is used to discover important patterns or structures from unlabeled data. Among unsupervised learning techniques, an autoencoder operates in a manner of learning major features of input data to remove noise. First, an encoder extracts low-dimensional features, and based thereon, a decoder restores original data from which noise has been removed. Through this, unnecessary noise can be effectively removed from an original signal.

In addition, among unsupervised learning techniques, clustering techniques including K-Means and DBSCAN are used to classify data into a plurality of groups. Noise patterns between frequencies and normal signals are automatically grouped.

In addition, among unsupervised learning techniques, principal component analysis PCA is a technique for extracting major components of data to reduce dimensionality. Through this, major feature components of the data are emphasized, and noise and signals can be distinguished.

In addition, among unsupervised learning techniques, a generative adversarial network GAN generates noise-removed signals by using two neural networks, namely, a generator and a discriminator. The generator generates a signal from which noise has been removed, and the discriminator evaluates quality of the signal. These two networks generate an optimal noise-removed signal through iterative learning.

In addition, among unsupervised learning techniques, hierarchical clustering is a method of forming hierarchical clusters based on similarity between data. By using this method, noise data and normal data can be divided into upper-level and lower-level groups, thereby enabling a structure of the data to be more clearly identified.

In addition, among unsupervised learning techniques, t-distributed stochastic neighbor embedding t-SNE enables high-dimensional data to be visualized in two dimensions or three dimensions, thereby allowing a structure of the data to be more easily understood. This technique is a useful method for visually detecting noise and signal patterns.

Meanwhile, the artificial intelligence model 132 may also be trained using a supervised learning technique. Supervised learning is a method of training the artificial intelligence model 132 using labeled data and predicting an accurate output for a given input. In this process, the artificial intelligence model 132 is trained based on input data and corresponding labels output data, and through this, accurate prediction can be performed for new data. For example, the model is trained using input data including noise and corresponding output data that are noise-removed data. The trained artificial intelligence model 132 is able to effectively remove noise from the input data and predict accurate impedance values. That is, the artificial intelligence model 132 operates in a manner of receiving data including noise and providing an accurate output corresponding thereto.

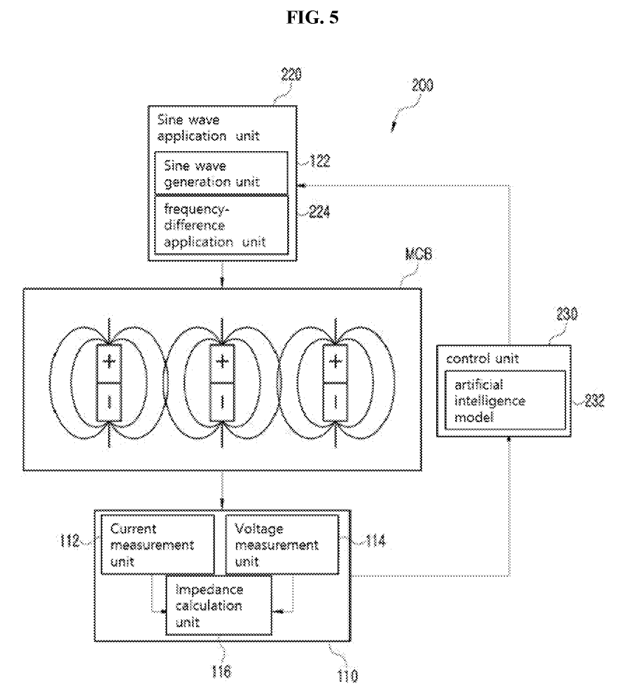

FIG. 5 is a block diagram for describing an impedance measurement device for a multi-channel battery according to another embodiment of the present invention.

Referring to FIG. 5, an impedance measurement device 200 for a multi-channel battery according to another embodiment of the present invention includes an impedance measurement unit 110, a sine wave application unit 220, and a control unit 230, and measures impedance of a multi-channel battery including a plurality of batteries.

The impedance measurement unit 110 includes a current measurement unit 112, a voltage measurement unit 114, and an impedance calculation unit 116, and measures impedance of a multi-channel battery MCB. Since the impedance measurement unit 110 illustrated in FIG. 5 is the same as the impedance measurement unit 110 illustrated in FIG. 1, the same reference numerals are assigned thereto and a detailed description thereof will be omitted.

The sine wave application unit 220 includes a sine wave generation unit 122 and a frequency-difference application unit 224, and applies sine waves having frequency differences to a multi-channel battery MCB including a plurality of batteries.

Since the sine wave generation unit 122 is the same as the sine wave generation unit 122 illustrated in FIG. 1, the same reference numeral is assigned thereto and a detailed description thereof will be omitted.

The frequency-difference application unit 224 reduces noise by applying alternating current voltages having different frequencies to a plurality of battery channels. When frequencies applied to respective battery channels are set to be different, measurement signals of the respective battery channels are separated in a frequency domain and do not interfere with signals of other battery channels. Accordingly, since noise generated at different frequencies does not mutually interfere, independent measurement for each battery channel is possible.

The control unit 230 includes an artificial intelligence model 232, and controls the sine wave application unit 220 based on impedance measured by the impedance measurement unit 110 so as to process and apply sine waves having different frequencies in order to reduce noise between batteries. In this embodiment, the artificial intelligence model 232 is similar to the artificial intelligence model 132 described with reference to FIG. 4. However, an optimal sine wave as an output value is a sine wave determined with a different frequency range to be applied to each battery channel. The frequency is an important parameter for optimizing battery performance and presents an optimal charging and discharging cycle in each channel. Meanwhile, the optimal sine wave as an output value of the artificial intelligence model 232 may be a sine wave having different phase differences to be applied to each battery channel. Here, the phase difference is an adjustment value for creating optimized charging and discharging conditions by minimizing interactions between signals that may occur in each battery channel.

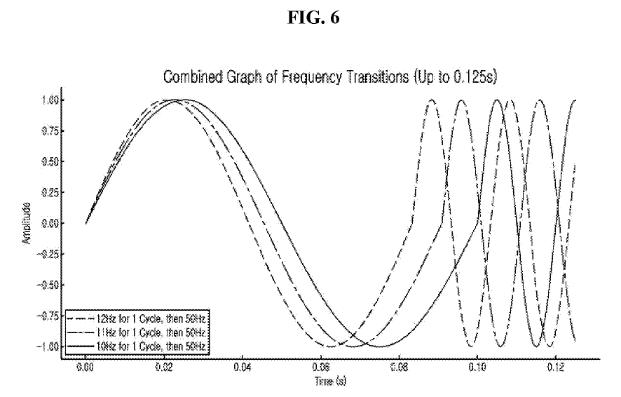

FIG. 6 is a graph illustrating an example of sine waves output from the sine wave application unit illustrated in FIG. 5.

Referring to FIG. 6, three sine wave signals have different frequencies in a first cycle and have the same frequency in a second cycle and subsequent cycles. That is, the three sine wave signals start with different frequencies, and after one cycle is completed, have the same frequency from a next cycle. Only when a first frequency is set differently and subsequent frequencies are set to be the same can respective measurement values be compared, and noise does not occur.

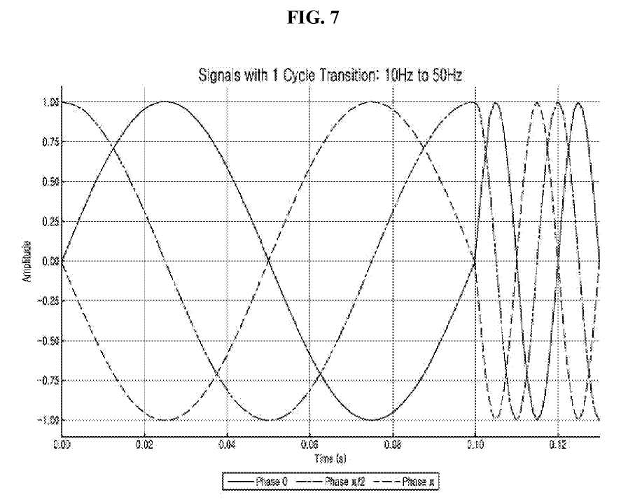

Although the sine wave application unit 220 described with reference to FIGS. 5 and 6 has been described as applying sine waves to a battery by varying frequencies of the sine waves to be applied, sine waves may also be applied by varying phase differences of the sine waves, as illustrated in FIG. 7 to be described later.

FIG. 7 is a graph illustrating another example of sine waves output from the sine wave application unit illustrated in FIG. 5. In particular, sine waves having phase differences are illustrated.

Referring to FIG. 7, three sine wave signals have different phases in a first cycle and have the same phase in a second cycle and subsequent cycles. That is, the three sine wave signals start with different phases, and after one cycle is completed, have the same phase in a next cycle. Only when a first phase is set differently and subsequent phases are set to be the same can respective measurement values be compared, and noise does not occur.

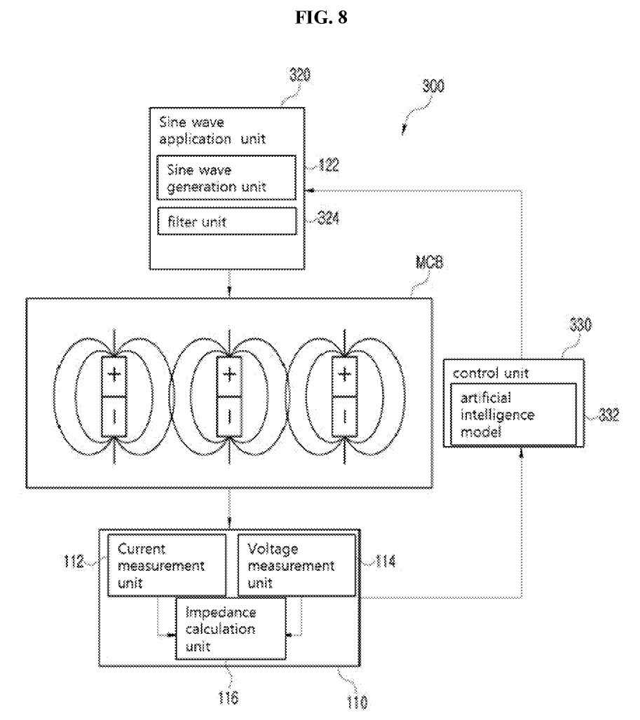

FIG. 8 is a block diagram for describing an impedance measurement device for a multi-channel battery according to still another embodiment of the present invention.

Referring to FIG. 8, an impedance measurement device 300 for a multi-channel battery according to still another embodiment of the present invention includes an impedance measurement unit 110, a sine wave application unit 320, and a control unit 330, and measures impedance of a multi-channel battery MCB including a plurality of batteries.

The impedance measurement unit 110 includes a current measurement unit 112, a voltage measurement unit 114, and an impedance calculation unit 116, and measures impedance of the multi-channel battery MCB. Since the impedance measurement unit 110 illustrated in FIG. 8 is the same as the impedance measurement unit 110 illustrated in FIG. 1, the same reference numerals are assigned thereto and a detailed description thereof will be omitted.

The sine wave application unit 320 includes a sine wave generation unit 122 and a filter unit 324, and applies noise-removed sine waves to a multi-channel battery MCB including a plurality of batteries.

Since the sine wave generation unit 122 is the same as the sine wave generation unit 122 illustrated in FIG. 1, the same reference numeral is assigned thereto and a detailed description thereof will be omitted.

The filter unit 324 is used to directly reduce noise included in a sine wave and removes unnecessary noise components from an alternating current voltage signal or a current signal. When measuring impedance of a battery, noise within a specific frequency range may be filtered by using a low-pass filter, a high-pass filter, or a band-pass filter. For example, when measuring battery impedance, very high-frequency noise may be included, and such high-frequency noise may be blocked from a signal by using a low-pass filter. In addition, as a method for filtering common-mode noise generated in a system, differential signal processing may be used, or noise may be removed by utilizing digital signal processing DSP technology.

The control unit 330 includes an artificial intelligence model 332, and controls the filter unit 324 to remove noise components of a sine wave by adjusting frequency parameters including a cutoff frequency and a bandwidth of a low-pass filter, a high-pass filter, or a band-pass filter in order to reduce noise between batteries.

As described above, one embodiment of the present invention provides a technology for accurately measuring impedance of a multi-channel battery and determining whether a battery is defective, and proposes methods of utilizing a time delay or a frequency difference or applying a filtering technique for noise reduction. Through this, interference between battery cells is minimized, and accurate impedance generated in each battery channel can be measured. In particular, by solving noise problems that may occur in a multi-channel system, a state of a battery can be more accurately identified and whether the battery is defective can be determined.

Although one embodiment of the present invention has been described above with reference to embodiments, those skilled in the art will understand that various modifications and changes may be made to one embodiment of the present invention without departing from the spirit and scope of one embodiment of the present invention as set forth in the appended claims.

### Detailed Description of Main Elements

110 : Impedance measurement unit 112 : Current measurement unit

114 : Voltage measurement unit 116 : Impedance calculation unit

120, 220, 320 : Sine wave application unit 122 : Sine wave generation unit

124 : Time-delay application unit 130, 230, 330 : Control unit

132, 232, 332 : Artificial intelligence model 224 : Frequency-difference application unit

324 : Filter unit MCB : Multi-channel battery

What is claimed is:

1. An impedance measurement device for a multi-channel battery including a plurality of batteries, comprising:
an impedance measurement unit configured to measure an impedance of the multi-channel battery including the plurality of batteries; and
a sine wave application unit configured to process a sine wave and apply the sine wave to each of the batteries in order to reduce noise between the batteries,
and further comprising a control unit including an artificial intelligence model, which receives, as input, multi-channel battery state information including voltage, current, temperature, and state of charge (SOC), and noise state information including a frequency interference pattern and external interference signal data, and outputs a sine wave to be applied to the multi-channel battery and a noise-removed impedance spectrum, wherein the control unit controls the sine wave application unit based on the impedance measured by the impedance measurement unit,
wherein the sine wave applied to each battery channel is distinct from one another to prevent signal interference between the battery channels, and
wherein the noise-removed impedance spectrum is generated by comparing actual full-spectrum data with measured frequency data to remove unnecessary noise.

2. The impedance measurement device for a multi-channel battery according to claim 1,
wherein the sine wave application unit includes a time-delay application unit for applying the sine wave to each of the batteries such that the sine waves applied to the respective batteries have a time delay.

3. The impedance measurement device for a multi-channel battery according to claim 1,
wherein the sine wave application unit includes a frequency-difference application unit for applying the sine wave to each of the batteries such that the sine waves applied to the respective batteries have a frequency difference.

4. The impedance measurement device for a multi-channel battery according to claim 1,
wherein the sine wave application unit includes a filter unit for removing noise from the sine wave applied to each of the batteries.
